(19) United States
(12) Patent Application Publication
(10) Pub. No.: US 2026/0237536 A1
(43) Pub. Date: Aug. 13, 2026

(54) X-RAY FOCUSING AND WAVELENGTH SELECTION

(71) Applicant: NOVA MEASURING INSTRUMENTS INC., Fremont, CA (US)

(72) Inventors: Bruno W. SCHUELER, San Jose, CA (US); Guorong V. ZHUANG, San Jose, CA (US); Gildardo DELGADO, Livermore, CA (US)

(73) Assignee: NOVA MEASURING INSTRUMENTS INC., Fremont, CA (US)

(21) Appl. No.: 19/469,332

(22) PCT Filed: Mar. 26, 2024
(86) PCT No.: PCT/IB2024/052907

§ 371 Date: Sep. 25, 2025

Related U.S. Application Data
(60) Provisional application No. 63/492,246, filed on Mar. 26, 2023.

(51) Int. Cl. G21K 1/06

(52) U.S. Cl. CPC G21K 1/06

(57) ABSTRACT

X-ray optics that include (i) achromatic collimating optics that is adapted to collimate an input X-ray beam to provide a collimated X-ray beam; (ii) an adjustable diffraction unit that is adapted to (a) receive the collimated X-ray beam, while being configured according to a current configuration that is associated with a current wavelength selected out of different wavelengths, the current configuration is selected out of different configurations that are associated with the different wavelengths, and (b) filter the collimated X-ray beam to provide a filtered collimated X-ray beam of the current wavelength; and (iii) achromatic focusing optics that is configured to focus the filtered collimated X-ray beam to provide a focused filtered X-ray beam.

### CROSS REFERENCE

This application claims priority from U.S. provisional patent application Ser. No. 63/492,246 filing date Mar. 26, 2023—which is incorporated herein by reference.

### BACKGROUND OF THE INVENTION

X-ray metrology in the Semiconductor metrology environment generally requires small footprint x-ray delivery and focusing systems. Since Fab space is expensive, many high brightness x-ray sources as employed in national labs utilizing Synchrotron radiation (SR), Free Electron Lasers (FEL), are not only prohibitive in operating cost but also too large to be used for metrology and inspection.

Other more scalable high brightness x-ray sources include electron beam induced gas or solid plasma sources, e-beam generated x-rays from solid targets (fluorescent of bremsstrahlung), e-beam/Liquid metal jet sources. Some select representative metrology applications are X-ray scattering (XRS), X-ray diffraction (XRD, Small angle X-ray Scattering (SAXS), X-ray Fluorescence (XRF) Total Reflection X-ray Fluorescence (TXRF), as well as X-ray Photoelectron Spectroscopy (XPS). Each of these applications require different range of exciting x-ray energies (wavelengths) and thus different focusing or collimating systems, as well as differences in x-ray energy bandwidth.

These systems are not flexible.

There is a growing need to provide a more flexible system.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1-7 illustrate examples of X-ray optics;

FIG. 8 illustrates an example of Bragg angle vs. x-ray wavelength for some select monochromator/diffractor crystals between from 0.6 to 20 A, and an example of Bragg angle vs. x-ray wavelength for some select monochromator/diffractor crystals between 20 and 120 A;

FIGS. 9-10 illustrate examples of X-ray optics;

FIGS. 11-12 illustrates examples of methods;

FIG. 13 illustrates an example of x-ray beam focusing from a finite x-ray source via an ellipsoidal or toroidal monochromator;

FIG. 14 illustrates an example of reflectivity of a multilayer substrate at fixed angle for an energy range from 100-1000 eV with strong suppression of other incoming x-ray lines;

FIG. 15 illustrates an example of x-ray focusing via a Schwarzschild Objective using multilayer coatings for low energy x-rays;

FIG. 16 illustrates an example of multilayer zone plate with slanted interfaces to meet Bragg angle;

FIG. 17 illustrates an example of x-ray transport through a poly-capillary lens; and

FIG. 18 illustrates an example of x-ray transport via reflective (Type I Wolters) optic.

### DETAILED DESCRIPTION OF THE DRAWINGS

There is provided a flexible x-ray micro-focusing systems for XPS/XRF metrology applications using different x-ray energies and energy bandwidth as a representative but not exclusive example which may readily be extended to other metrology use cases. In particular methods for focusing monochromatic x-ray beams of multiple but selectable energies to a wafer surface will be described. A flexible method for operating the system is also provided.

There is provided a flexible x-ray focusing systems incorporate dedicated x-ray optics which is not optimized for just a single and specific x-ray energy. The system exhibits high performance and flexibility—in contrary with prior art dedicated x-ray monochromatic focusing system that lack flexibility at the expense to achieve this performance. The system is more cost effective than prior art systems in which the cost factor becomes prohibitive where a larger range of X-ray energies is beneficial to the application, i.e., two or more monochromator focusing systems for two or more x-ray energies. Described are methods to enable X-ray beam transport systems to focus a multitude of selectable and monochromatic x-ray energies (wavelengths) through to the metrology site. X-ray targets from gas, solid, or liquid metal jet high brightness x-ray sources not only generate characteristic x-ray lines from the target but also varying intensity of continuum radiation knows as Bremsstrahlung.

High intensity continuum radiation can be used as excitation source for specific applications, in particular if the x-ray focusing system of compact scale can provide a continuously or quasi-continuously tunable monochromatic x-ray beam which can be focused to the metrology site. X-ray focusing system featuring a discretely selectable x-ray energy. X-ray focusing system may—but not exclusively—consist of fixed focusing elements in combination with a monochromator crystal or multilayer.

As a representative example, use of an achromatic point-to-parallel optics system from x-ray source a to flat monochromator crystal or multilayer providing a given Bragg angle Θ_{b}. A second reversed point-parallel optic is placed at the outgoing angle of the monochromator crystal to focus the x-ray beam to the metrology site.

According to an embodiment, there is provided X-ray optics that includes:
a. Achromatic collimating optics that is adapted to collimate an input X-ray beam to provide a collimated X-ray beam.
b. An adjustable diffraction unit that is adapted to (a) receive the collimated X-ray beam, while being configured according to a current configuration that is associated with a current wavelength selected out of different wavelengths, the current configuration is selected out of different configurations that are associated with the different wavelengths, and (b) filter the collimated X-ray beam to provide a filtered collimated X-ray beam of the current wavelength.
c. Achromatic focusing optics that is configured to focus the filtered collimated X-ray beam to provide a focused filtered X-ray beam.

According to an embodiment, the adjustable diffraction unit includes different diffraction elements that are associated with the different wavelengths.

According to an embodiment, the current configuration includes positioning one of the adjustable diffraction elements in the path of the collimated X-ray beam (while the other adjustable diffraction elements are located outside said path).

According to an embodiment the positioning includes at least one of:
a. Moving at least some of the different diffraction elements.
b. Moving other elements of the X-ray optics (such as the achromatic collimating optics and/or the achromatic collimating optics) in relation to the at least some of the different diffraction elements.
c. Moving the location of the input X-ray beam—using mechanical and/or optical means.

According to an embodiment, the movement is made along one axis, along multiple axis, is linear, is non-linear, is rotational, and the like.

According to an embodiment, an diffraction element is a grating, a multilayer diffractor, or any other diffraction element.

According to an embodiment, different diffraction elements are associated with the different wavelengths.

According to an embodiment, the different diffraction elements exhibit different lattice spacings.

According to an embodiment, the different diffraction elements exhibit different compositions.

According to an embodiment, the diffraction elements are different plane gratings, that are associated with the different wavelengths.

According to an embodiment, the different diffraction elements are arranged in an array or in an unordered manner. The array may be a linear array, a multi-dimensional array, a radially symmetrical array or any other non-linear array.

According to an embodiment, the different diffraction elements are arranged in a linear array, and wherein the configuration unit is configured to move one of the different diffraction elements into a path of the collimated X-ray beam.

According to an embodiment, the different diffraction elements are connected to a turret, and wherein the configuration unit is configured to move one of the different diffraction elements into a path of the collimated X-ray beam.

According to an embodiment, the different diffraction elements includes different ellipsoid monochromators that are associated with the different wavelengths.

According to an embodiment, the different diffraction elements further includes demagnifying optics.

According to an embodiment, the X-ray optics include a configuration unit for selecting one of the different diffraction elements to interact with the collimated X-ray beam. The configuration unit may be a controller.

According to an embodiment, the adjustable diffraction unit includes a diffraction element; and a configuration unit that is configured to determine a Bragg condition of the diffraction element.

According to an embodiment, the configuration unit is configured to set an optical axis of the collimated X-ray beam, an optical axis of the filtered collimated X-ray beam and a distance between the diffraction element and at least one of the collimating optics or the focusing optics.

According to an embodiment, the configuration unit is configured to set the optical axis of the collimated X-ray beam by rotating the collimating optics and to set the optical axis of the filtered collimated X-ray beam by rotating the focusing optics, while maintaining constant source-to-focus distance.

According to an embodiment, the adjustable diffraction unit includes different diffraction elements that are associated with the different wavelengths, wherein the different diffraction elements includes the diffraction element, and wherein the configuration unit is further configured to select one of the diffraction elements to interact with the collimated X-ray beam.

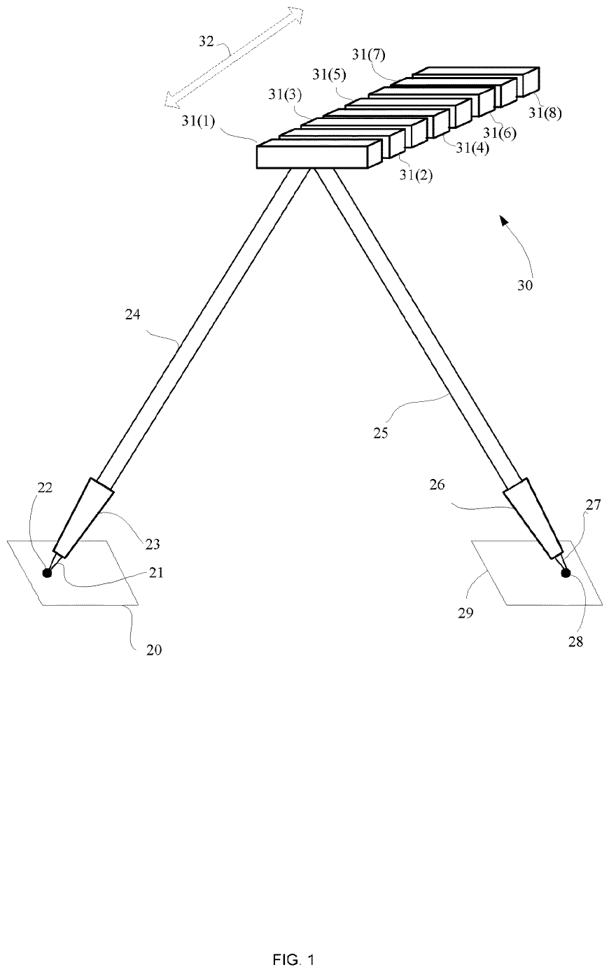

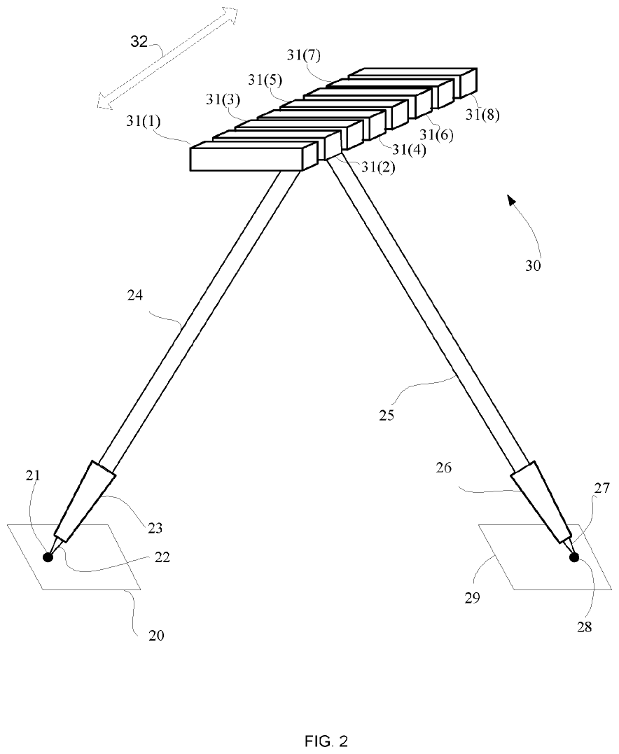

FIGS. 1-2 illustrates several diffraction elements such as crystal diffractors 31(1)-31(8) with the same Bragg condition arranged side-by-side and movable along first axis 32—for selection of one of the crystal diffractors at a given moment in time. In FIG. 1 the first crystal diffractor 31(1) is selected—while in FIG. 2 the third crystal diffractor 31(3) is selected.

Both FIGS. 1 and 2 also illustrates a source 20, an initial spot 21 formed on the source, input X-ray 22 that is collimated by achromatic collimating optics 23 that is adapted to collimate an input X-ray beam to provide a collimated X-ray beam 24.

The collimated X-ray beam 24 impinges in a selected crystal diffractor (associated with a current wavelength) which filters the collimated X-ray beam to provide filtered collimated X-ray beam 25 that exhibits the current wavelength.

Achromatic focusing optics 26 is configured to focus the filtered collimated X-ray beam 25 to provide a focused filtered X-ray beam 27 that impinges on a target 29 and forms a spot 28 on the target. The target may be a sample or a part of the sample.

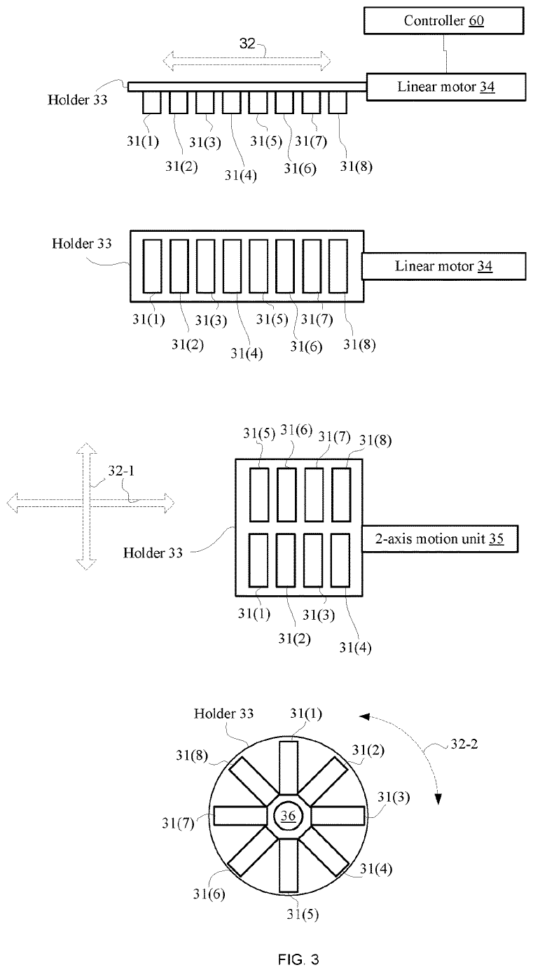

FIG. 3 illustrates examples of moving different crystal diffractors 31(1)-31(8) using linear movement along one axis (see dashed arrow 32), along two axes (see dashed arrows 32-1), using a rotational movement (see dashed arrow 32-2), using different holders 33 for providing a mechanical coupling between the different crystal diffractors and movement elements such as rotational motor 36, linear motor 34 or, 2-axis motion unit 35. According to an embodiment the movement is controlled by controller 60 that may include one or more parts of one or more integrated circuits.

To provide an example, for an assumed Bragg angle of 60 degree, the X-ray optics of FIGS. 1-2 could be applicable for the following x-ray energies using selectable monochromator crystals at fixed height and angle as listed below in table 1:

| crystal | E | λ | 2d | Bragg |
|---|---|---|---|---|
| diffractor | [ev] | [A] | [A] | degree |
| LiF 422 | 8667 | 1.430532 | 1.652 | 59.990 |
| Ge 422 | 6171 | 2.009143 | 2.32 | 59.998 |
| LiF 220 | 5027 | 2.466367 | 2.848 | 59.997 |
| Si 220 | 3728 | 3.325758 | 3.840312 | 59.999 |
| CaCO3 200 | 2359 | 5.255797 | 6.071 | 59.965 |
| Ge 111 | 2192 | 5.656216 | 6.532 | 59.988 |
| InSb 111 | 1914 | 6.477756 | 7.4806 | 59.990 |
| SiO2 100 | 1682 | 7.371239 | 8.512 | 59.995 |
| ADP 101 | 1346 | 9.211311 | 10.64 | 59.966 |
| SHA 110 | 1024.5 | 12.10193 | 13.98 | 59.958 |
| Mica 002 | 721.6 | 17.18185 | 19.84 | 59.999 |
| RHP 100 | 548.2 | 22.61661 | 26.121 | 59.979 |
| W Si* | 238.64 | 51.95451 | 60 | 59.987 |
| CrTi* | 179 | 69.26494 | 80 | 59.976 |

Table 1 illustrates an approximate transmitted and focusable x-ray energies for different monochromator crystals and multilayers at an assumed fixed Bragg angle of 60 degree with achromatic input and output optics.

Multilayers diffractors can be optimized for different x-ray energies by utilizing different material combinations, layer ratio and thickness, as well as number of layers on the substrate. This applies for WSi and CrTi multilayers.

FIGS. 1-2 illustrates an example of X-ray transport from x-ray source via point-to-parallel optics to monochromator and focusing the resultant monochromatic discretely selectable x-ray beam to a metrology site.

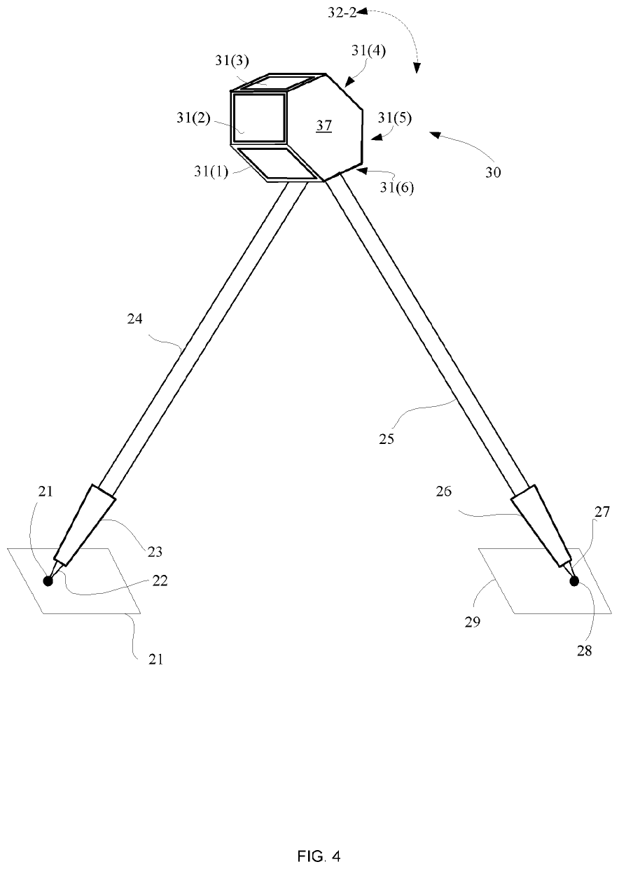

FIG. 4 illustrates a depiction of a six-crystal or multilayer diffractors 31(1-31(6) mounted in a turret 37 that is rotatable about an axis. FIG. 4 also illustrates source 20, initial spot 21, input X-ray 22, achromatic collimating optics 23, collimated X-ray beam 24, filtered collimated X-ray beam 25, achromatic focusing optics 26, focused filtered X-ray beam 27, target 29 and spot 28.

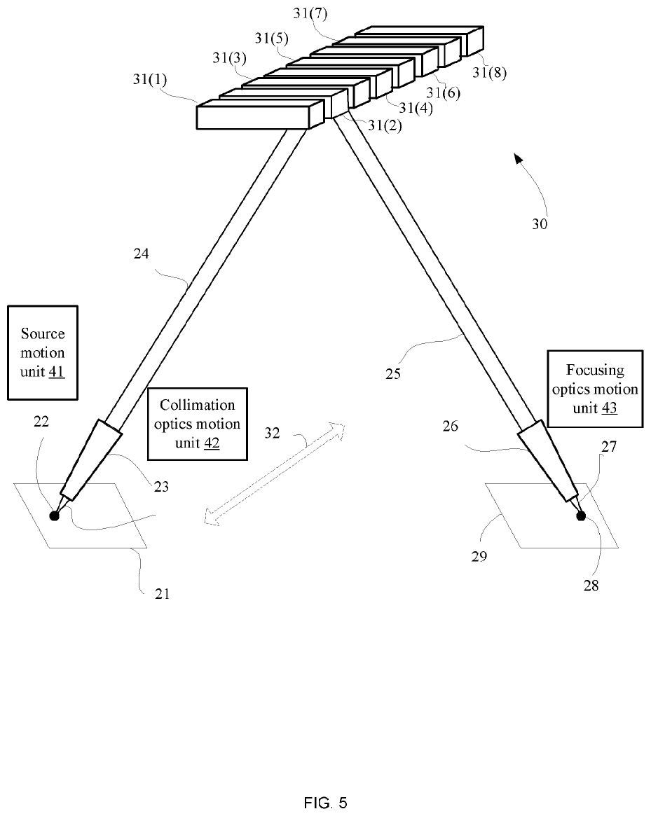

FIG. 5 illustrates X-ray optics that differ from the X-ray optics of FIG. 1—by maintaining the crystal diffractors static and moving other parts of the X-ray optics—such as the achromatic collimating optics 23 (movement using collimation optics motion unit 42) and the achromatic focusing optics 26 (movement using focusing optics motion unit 43) and/or by moving the x-ray source (of the location of the spot 22)—using the source motion unit 41. The linear movement is illustrated by dashed arrow 32.

According to an embodiment, more flexible method to enable quasi-continuous x-ray focusing can be achieved by changing a combined tilt of the input and output optics (including, for example the achromatic collimating optics 23 and the achromatic focusing optics 26, respectively) in order to change the Bragg condition.

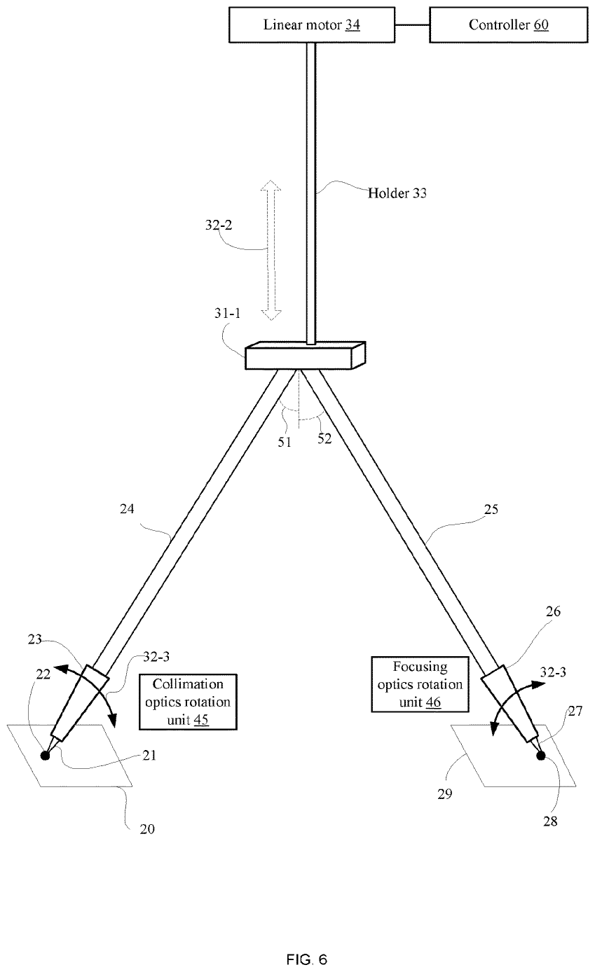

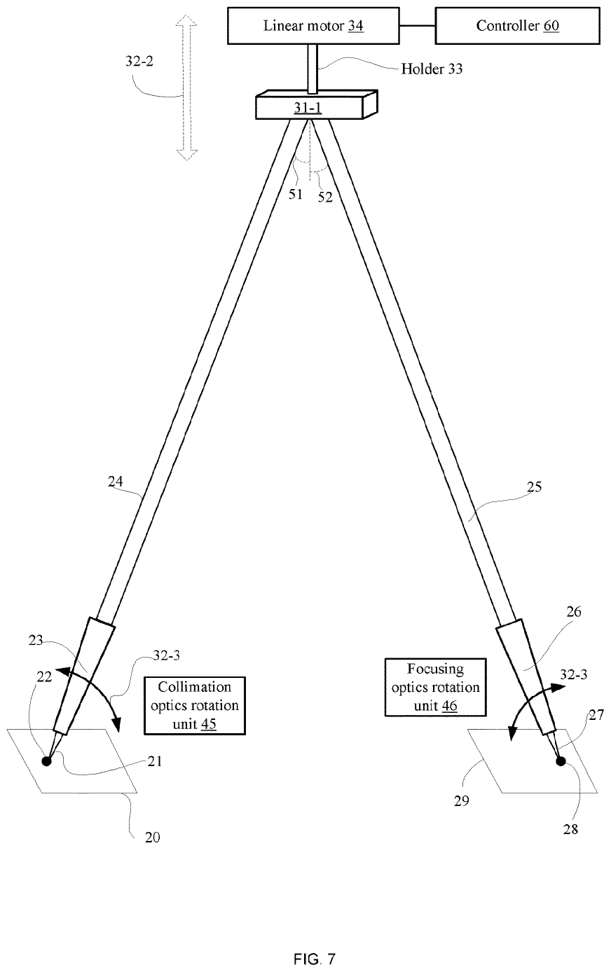

FIGS. 6 and 7 illustrate two different positions (height or distance from the target) of a diffraction element 31-1—whereas the two different positions are associated with different Bragg angles and different tilt angles (see curved arrows 32-2 indicative of a rotational movement) of the achromatic collimating optics 23 and the achromatic focusing optics 26. Collimating optics rotation unit 45 rotates the achromatic collimating optics 23. Focusing optics rotation unit 46 rotates the achromatic focusing optics 26.

Since a change in Bragg angle (denoted 51 and 52) also alters the outgoing monochromated x-ray beam toward the final focusing optics, the distance of crystal-to-input and final focusing optics has to be changed at the same time.

For shallower Bragg angles, i.e., higher energy x-ray transport, the emission point-to-diffractor crystal must be reduced, the diffractor stage system moved closer to the incoming parallel x-ray beam, as well as the opposite angular compensation of the focusing optics (opposite sign or the source focusing optics) to allow for a stationary fixed x-ray spot at the metrology site.

The X-ray optics of FIGS. 6 and 7 can be used for a fixed source-to-metrology distance. Especially—the X-ray transport and semi-continuous x-ray energy transport from source to target (metrology site) is very flexible and may provide a solution to a continuous of semicontinuous range of wavelengths.

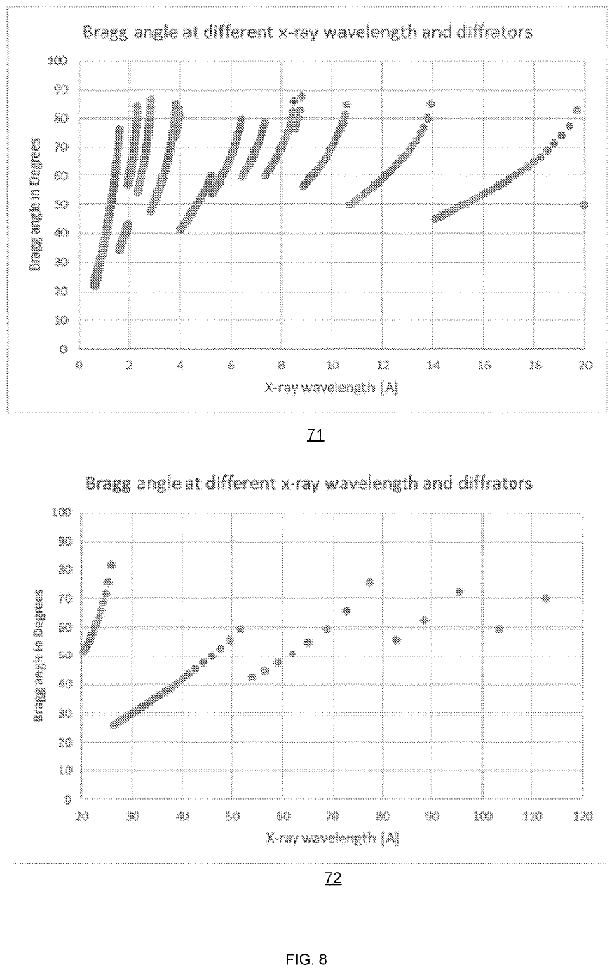

Graph 71 of FIG. 8 illustrates Bragg angle vs. x-ray wavelength for some select monochromator/diffractor crystals between from 0.6 to 20 A

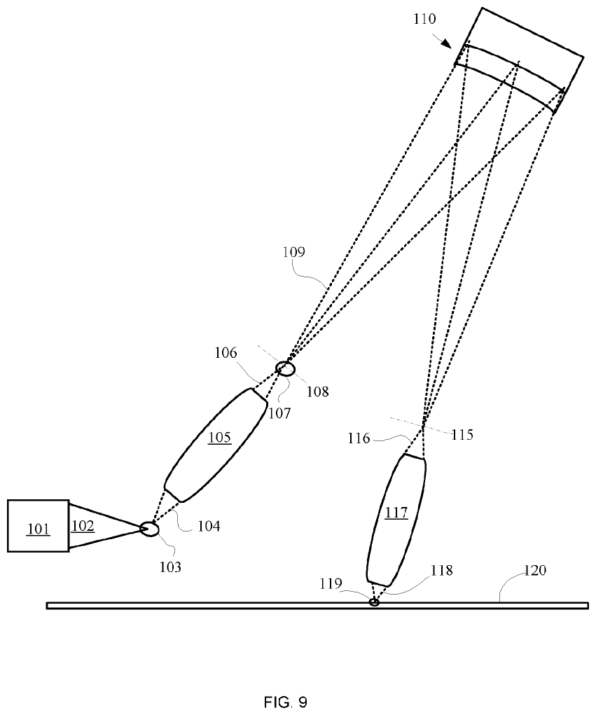

Graph 72 of FIG. 9 illustrates Bragg angle vs. x-ray wavelength for some select monochromator/diffractor crystals between 20 and 120 A. This figure illustrates the applicable x-ray wavelength range for some representative monochromating/diffractor crystals.

The focusing input and output optics can include a nested Wolters optics, including central poly-capillary optics. Input and output optics may have different focal length.

The more flexible method illustrated above can be extended using a set several of monochromator crystals mounted on a turret or linear translator which can be moved into the incoming x-ray beam path.

The suggested solution provides a system that is compact, and is step-wise energy selectable x-ray focusing system for semiconductor metrology. The system is capable to transporting and focusing a monochromatic x-ray beam spanning and applicable to x-rays from some 100 eV to several keV.

The system is a compact quasi-continuous x-ray energy focusing system to direct and focus a monochromatic x-ray beam to the metrology site. The system is capable to transport and focus a monochromatic x-ray beam spanning and applicable to x-rays from some 100 eV to several keV.

The mentioned above solution may exhibit at least one of the following:
a. X-ray transport from a polychromatic or partially monochromatic x-ray source beam of <100 m in diameter through an optics configuration that results in a monochromatic focus at the analysis site.
b. A system to collect x-rays, monochromate the x-ray beam, and subsequently focus to the analysis site.
c. Provide x-ray focusing of monochromated x-ray beam of stepwise selectable energy which is focused onto the metrology site.
d. A continuously energy-tunable x-ray focusing system over a limited energy range of x-rays.

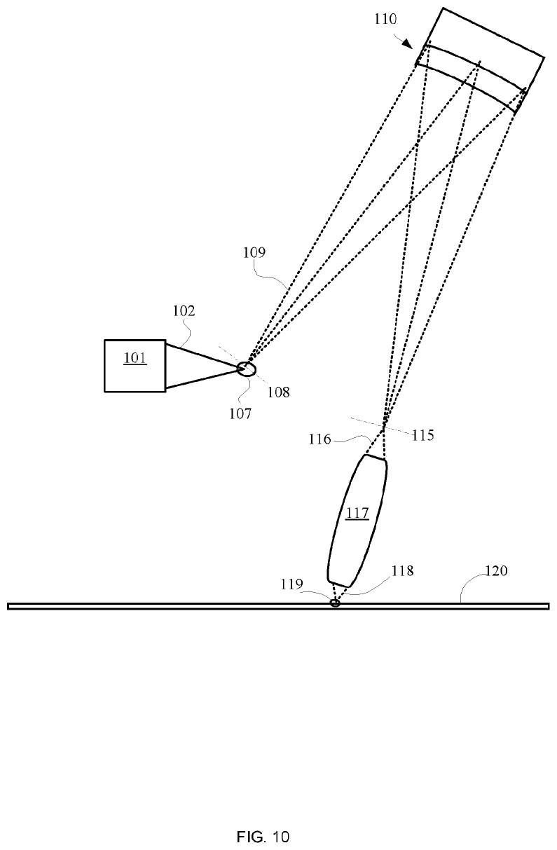

FIGS. 9 and 10 illustrates example of X-ray optics that include:
a. A focusing monochromator 110 that is configured to (i) receive a non-collimated input X-ray beam 109, wherein at a first plane 108 the non-collimated input X-ray beam forms a first spot 103 on a target, (ii) filter and focus the non-collimated X-ray beam to provide a filtered focused X-ray beam 116 of a current wavelength. According to an embodiment, the focusing monochromator is an ellipsoid shaped monochromator or a toroid shaped monochromator.
b. Demagnifying achromatic optics 117 configured to demagnify the filtered focused X-ray beam of a current wavelength to form, at a sample plane 120, a target spot 119 that is smaller than the first spot 103. The demagnifying achromatic optics 117 outputs yet another non-collimated X-ray beam 119.

According to an embodiment, the first spot is imaged to a second plane 115 that is located between the focusing monochromator 110 and the demagnifying achromatic optics 117. The first plane 108 and the second plane 115 and conjugate planes.

In FIG. 9 the X-ray optics also include imaging achromatic optics 105 that receives an input X-ray beam 104. The X-ray beam 104 is generated by illuminating a target with a laser beam 102 (generated by a laser source 101) to form a spot 103 on the target. The imaging achromatic optics 105 outputs another non-collimated X-ray beam 106 that forms a spot 107 at first plane 108.

In FIG. 10, the X-ray beam source (for example a target illuminated with a laser beam 102 generated by laser source 101) is located at the first plane.

According to an embodiment, the X-ray optics of any one of FIG. 9 or 10 may be a part of an adjustable X-ray optics.

According to an embodiment, there is provided a X-ray optics that includes different focusing monochromators associated with different wavelengths.

### Demagnification

According to an embodiment, the collection efficiency as well as the final spot size of an x-ray focusing system for a specific single x-ray energy is controlled or improved by using a focusing optics imaging the x-ray source emission spot to a focal point of an ellipsoidal or Toroidal monochromator for a specific x-ray energy.

A monochromatic x-ray focus of the monochromator is imaged onto the wafer surface. Alternatively—second optics placed at the conjugate image location of the monochromator to image/demagnify the monochromatic x-ray beam spot to the wafer.

An ellipsoidal or Toroidal monochromator with source conjugate placed at the x-ray source emission region which produces a monochromatic focus at the image conjugate point/distance for a specific x-ray energy.

A focusing optics placed at the monochromator image spot which may be used to de-magnify the monochromatic image onto the wafer to a spot size smaller than the spot generated at the monochromator focus.

The imaging optics may be an achromatic reflective or polycapillary optics.

According to an embodiment there is provided an X-ray optics that includes an x-ray collection system configured to focus the polychromatic source at the source conjugate of a focusing monochromator (ellipsoidal or toroidal shape) and demagnify the image conjugate of the monochromator via fully focusing optics onto the wafer or mask metrology site. The final focus on the target (for example—wafer) will be smaller than the spot size achievable with a monochromator alone—see, for example FIGS. 9 and 10).

According to an embodiment, a source imaging optics is employed to optimize the x-ray collection efficiency from x-ray source to (focusing) monochromator source conjugate, in order to minimize/optimize monochromator size and shape for lower brightness x-ray sources.

According to an embodiment, the X-ray optics is simplified and provides selectable demagnification of an ellipsoidal or toroidal monochromator by placing a de-magnifying achromatic x-ray optic (reflective or polycapillary) at the image conjugate of a fixed magnification monochromator. The final x-ray spot size at the wafer metrology site can thus be monochromatic and smaller than achievable with a focusing monochromator alone.

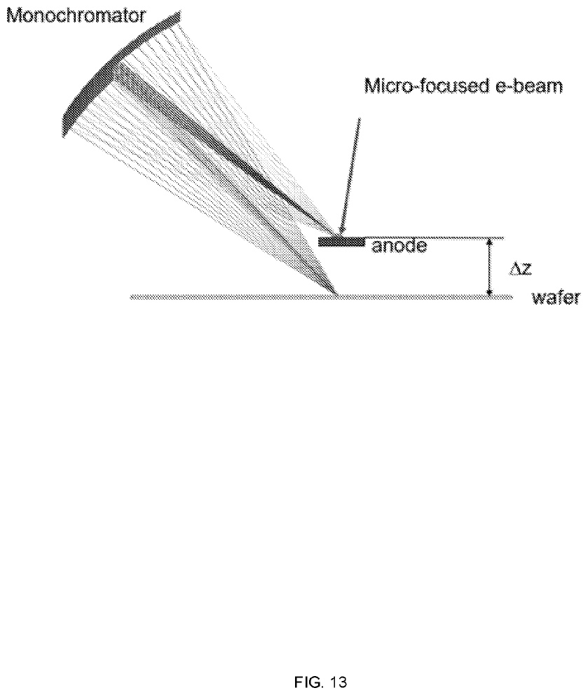

According to an embodiment the suggested demagnification is applied to optics illustrated in FIG. 13 or other X-ray optics.

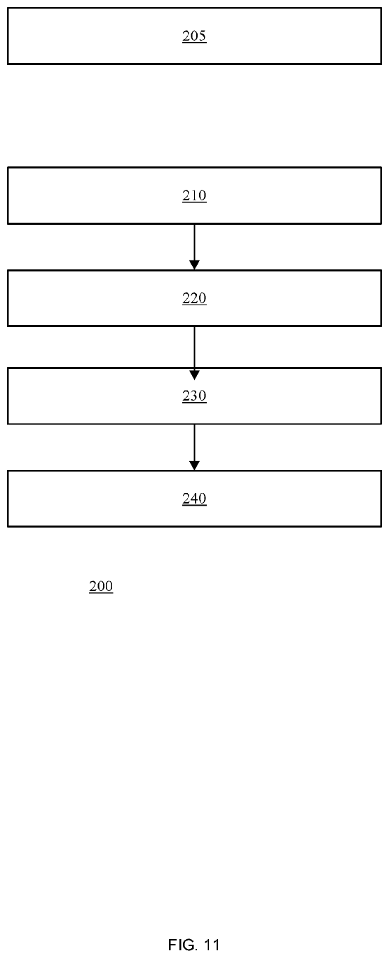

FIG. 11 illustrates an example of method 200 for manipulating an input X-ray.

According to an embodiment, method 200 includes step 210 of collimating, by achromatic collimating optics, the input X-ray beam to provide a collimated X-ray beam.

According to an embodiment, step 210 is followed by step 220 of receiving, by an adjustable diffraction unit the collimated X-ray beam, while being configured according to a current configuration that is associated with a current wavelength selected out of different wavelengths, the current configuration is selected out of different configurations that are associated with the different wavelengths.

According to an embodiment, step 220 is followed by step 230 of filtering, by the adjustable diffraction unit, the collimated X-ray beam to provide a filtered collimated X-ray beam of the current wavelength.

According to an embodiment, step 230 is followed by step 240 of focusing, by achromatic focusing optics, the filtered collimated X-ray beam to provide a focused filtered X-ray beam.

According to an embodiment, method 200 is implemented by any of the X-ray optics illustrated in any one of FIGS. 1-7.

According to an embodiment method 200 include selecting a current configuration and/or receiving an request or instruction to apply a current configuration—and configuring 205 the adjustable diffraction unit to the current configuration.

What amounts to the current configuration may change over time.

Examples of configuring include
a. Moving at least some of the different diffraction elements.
b. Moving other elements of the X-ray optics (such as the achromatic collimating optics and/or the achromatic collimating optics) in relation to the at least some of the different diffraction elements.
c. Moving the location of the input X-ray beam—using mechanical and/or optical means.
d. Moving an adjustable diffraction element and/or changing tile angle of various optics.

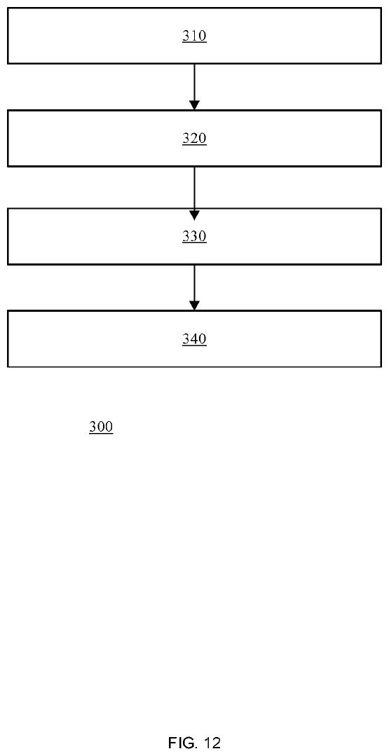

FIG. 12 illustrates an example of a method 300 for manipulating an X-ray.

According to an embodiment, method 300 includes step 310 of receiving, by a focusing monochromator, a non-collimated input X-ray beam, wherein at a first virtual plane the non-collimated input X-ray beam forms a first spot.

According to an embodiment, step 310 is followed by step 320 of filtering and focusing, by the focusing monochromator, the non-collimated X-ray beam to provide a filtered focused X-ray beam of a current wavelength.

According to an embodiment, step 330 is followed by step 340 of demagnifying, by demagnifying achromatic optics, the filtered focused X-ray beam of a current wavelength to form, at a sample plane, a target spot that is smaller than the first spot.

According to an embodiment, the first spot is imaged to a second plane that is located between the focusing monochromator and the demagnifying achromatic optics, wherein the first plane and the second plane and conjugate planes.

According to an embodiment, an X-ray beam source is located at the first plane.

According to an embodiment, method 300 includes imaging, by an imaging achromatic optics a spot formed by the X-ray beam source onto the first plane.

Any combination of any steps of method 200 and method 300 may be provided.

According to an embodiment, method 300 is executed by any of the X-ray optics of FIG. 9 or 10.

### Various Example of Other Systems

The most commonly x-ray energy utilized in XPS is AlKα (1486.7 eV) which is typically transported and focused onto a wafer surface via a monochromator in order to narrow the natural line width of the emission line for chemical state identification. Photoelectrons generated by AlKα radiation will have a kinetic maximum energy of ~1486.7 eV, thus limiting the analysis depth to ~10 nm and provides a limited range of secondary x-ray fluorescence lines which can be detected simultaneously and used as independent and complementary input parameter for the total dose of the analyzed material. The most commonly used focusing and monochromator system consists of an ellipsoidal or toroidal substrate (see FIG. 13) populated with quartz crystal platelets and provides point-to point focus of the target emission to the sample surface with an energy bandwidth ~0.5 eV. The advantage of these systems is that monochromators with large angular acceptance and thus high transport efficiency can be manufactured. A monochromator focusing system of this type may also transport when optimized for the 1^{st} order Bragg diffraction for AlKα can also focus discrete higher order diffraction orders (energies) according to nλ=2d sin(Θ) (d is the crystal lattice spacing) to the wafer surface. However, the coverage of focusable energies is discrete by nature and intermediate energies other than nλ equivalent can by design not be transported to the sampling area. Lower x-ray energies are not accessible or focusable at the sample surface with such a monochromator and would require a larger 2d lattice spacing applied to the substrate.

Systems may monochromate and focus different x-ray wavelengths λ as given by hc/E where h is Planck's constant, c=speed of light, and E the x-ray energy can be produced by applying crystals of different crystal plane orientation and/or crystal materials to an ellipsoidal substrate. The limitation that only x-ray energies according to nλ=2d sin(Θ) or E=n/[(hc)2d sin(Θ)] can be monochromated and focused onto a wafer site with the lower cut-off determined by the 2d crystal lattice spacing. The higher the 1^{st} order diffraction Energy, the larger the larger the energy difference of higher diffraction orders.

In general, monochromator crystals for the higher energy range require smaller 2d lattice spacing and are quite readily available using various crystal plane orientations and crystals. These crystals can be applied to a substrate and focus monochromatic x-rays to the sampling region.

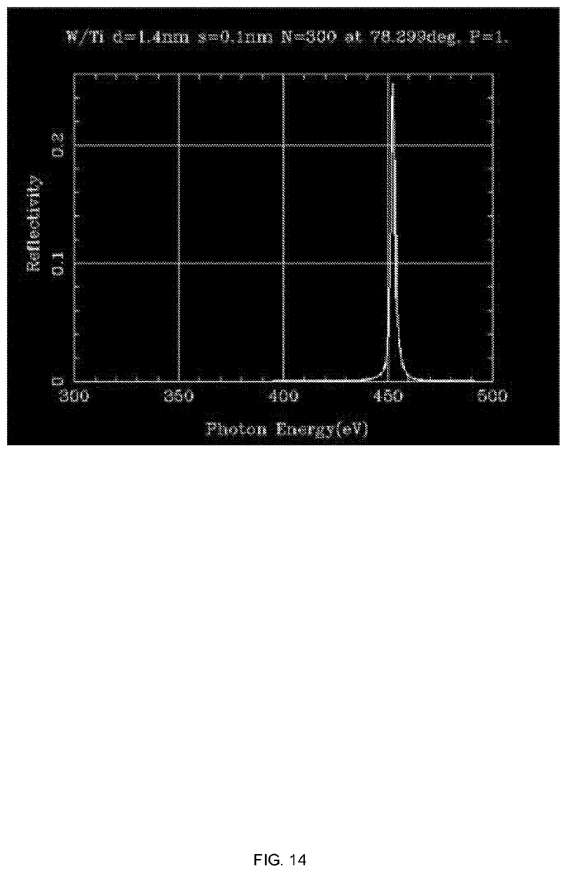

For X-ray energies requiring 2d-lattice spacings larger than 27 A, natural crystals are no longer available with defined lattice structure and multilayer mirror monochromators are used. Multilayers can be deposited on a substrate—for example an ellipsoidal substrate-to focus a monochromatic x-ray beam from the x-ray source to the sampling surface. A specific example may be use of a W/Ti multilayer with 1.4 nm period and relative layer thickness of 0.55 having three hundred repeating layers onto the substrate. For example, for an x-ray energy of 452.2 eV (Ti La), maximum reflectivity ideally 25% occurs at a Bragg angle of 78.3 degrees (cxro website). This engineered multilayer on a substrate provides a monochromatic x-ray beam that is focusable on to a wafer substrate (see FIGS. 13 and 14).

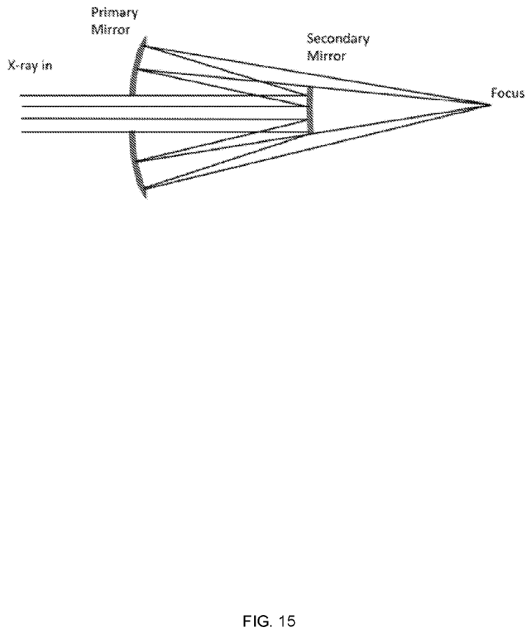

Following this method, such a multilayer structure can be deposited on other optical systems, such as a Schwarzschild objective of suitable focusing geometry to provide a largely monochromatic and focused beam spot on a target sampling area (see FIG. 15). The Schwarzschild optics is primarily applicable for the low-energy x-ray range in the water window since it requires a near-normal reflection geometry, i.e., Bragg angles in the range of >80 and <90 degrees.

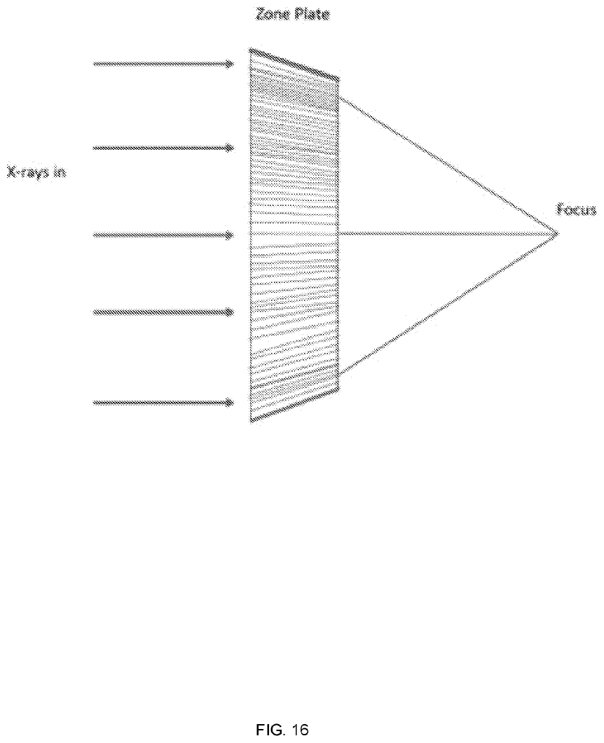

Zone Plate optics represent another type of energy-selective focusing systems and are typically based on multilayers. These systems may provide focusing in Laue transmission (FIG. 16 illustrates a Schematic of multilayer zone plate with slanted interfaces to meet Bragg angle) mode or in a reflective configuration. The principle is based a set of concentric ellipses around the object point with increasing size and common foci (source-object) to satisfy the Bragg diffraction condition over a larger diameter: rₙ=sqrt[(nλ/2)²+nλf], where f is the focal length.

The resolution of zone plates is determined by the outermost zone width.

Reflection off-axis zone plate structures having appropriate geometry can be deposited on a substrate to provide spatially separated x-ray images according to incoming wavelength for a polychromatic incoming x-ray beam.

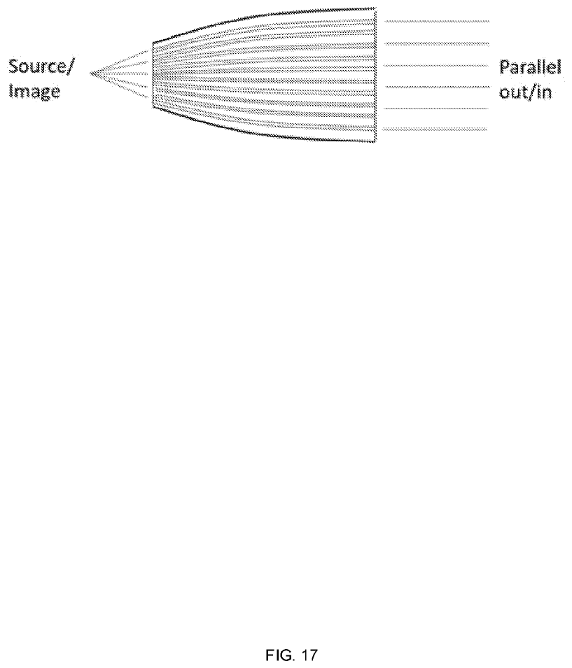

Non-energy selective (achromatic) focusing systems operate using total external or internal reflection. For x-ray energies well above 2-3 keV, the most commonly employed focusing optics is poly-capillary optics. The focusing system consist of bundled glass capillaries which can be shaped to provide either point-to-parallel, parallel-point, or point-to-point focus and utilize total internal reflection (see FIG. 17—Schematic x-ray transport through a poly-capillary lens)

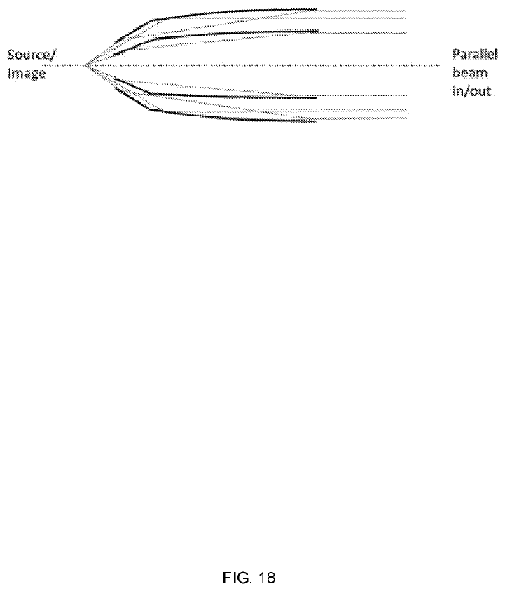

For the lower energy range the effectiveness of poly-capillary optics is generally lower than shaped reflective optics mirrors due to the higher critical angle of metal coated surfaces, for example Pt or other metal coating. The reflective optics can be shaped to provide similar focusing conditions as poly-capillary systems, i.e., provide point-to-parallel, parallel-point, or point-to-point focus. The shape of the reflective optics for point-to parallel x-ray transport is an effective paraboloid, shaped to match a given working distance as illustrated in FIG. 16. Single-bounce optics must employ a true parabolic shape and can be highly efficient for an x-ray energy range of several keV (depending on the metal coating). Type 1 through 3 Wolters optics utilizes total reflection as well, in double-bounce geometry with nested parabolic and elliptical mirrors to focus a near-parallel beam to a point (and the reverse a point to parallel beam) (see FIG. 18—Schematic x-ray transport via reflective (Type I Wolters) optic).

In select applications, Reflective Wolters optics and Poly-capillary optics have been used in combination to increase the wavelength range of the collimating or focusing optics, i.e., poly-capillary optics inside Wolters optic.

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that may be executed by the system.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein may be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed:

1. X-ray optics, comprising:
i. achromatic collimating optics that is adapted to collimate an input X-ray beam to provide a collimated X-ray beam;
ii. an adjustable diffraction unit that is adapted to (a) receive the collimated X-ray beam, while being configured according to a current configuration that is associated with a current wavelength selected out of different wavelengths, the current configuration is selected out of different configurations that are associated with the different wavelengths, and (b) filter the collimated X-ray beam to provide a filtered collimated X-ray beam of the current wavelength; and
iii. achromatic focusing optics that is configured to focus the filtered collimated X-ray beam to provide a focused filtered X-ray beam.

2. The X-ray optics according to claim 1, wherein the adjustable diffraction unit comprises different diffraction elements that are associated with the different wavelengths.

3. The X-ray optics according to claim 2, wherein the different diffraction elements exhibit different lattice spacings.

4. The X-ray optics according to claim 2, wherein the different diffraction elements exhibit different compositions.

5. The x-ray optics according to claim 2 wherein the different diffraction elements are different plane gratings, that are associated with the different wavelengths.

6. The X-ray optics according to claim 2, wherein the different diffraction elements are arranged in linear array, and wherein a configuration unit is configured to move one of the different diffraction elements into a path of the collimated X-ray beam.

7. The X-ray optics according to claim 2, wherein the different diffraction elements are connected to a turret, and wherein a configuration unit is configured to move one of the different diffraction elements into a path of the collimated X-ray beam.

8. The X-ray optics according to claim 2, wherein the different diffraction elements comprise different ellipsoid monochromators that are associated with the different wavelengths.

9. The X-ray optics according to claim 2, wherein the different diffraction elements further comprise demagnifying optics.

10. The X-ray optics according to claim 2, further comprising a configuration unit for selecting one of the different diffraction elements to interact with the collimated X-ray beam.

11. The X-ray optics according to claim 1, wherein the adjustable diffraction unit comprises:
i. a diffraction element; and
ii. a configuration unit that is configured to determine a Bragg condition of the diffraction element.

12. The X-ray optics according to claim 11, wherein the configuration unit is configured to set an optical axis of the collimated X-ray beam, an optical axis of the filtered collimated X-ray beam and a distance between the diffraction element and at least one of the achromatic collimating optics or the achromatic focusing optics.

13. The X-ray optics according to claim 12, wherein the configuration unit is configured to set the optical axis of the collimated X-ray beam by rotating the achromatic collimating optics and to set the optical axis of the filtered collimated X-ray beam by rotating the achromatic focusing optics, while maintaining constant source-to-focus distance.

14. The X-ray optics according to claim 13, wherein the adjustable diffraction unit comprises different diffraction elements that are associated with the different wavelengths, wherein the different diffraction elements comprise the diffraction element, and wherein the configuration unit is further configured to select one of the diffraction elements to interact with the collimated X-ray beam.

15. A method for manipulating an input X-ray beam, the method comprising:
i. collimating, by achromatic collimating optics, the input X-ray beam to provide a collimated X-ray beam;
ii. receiving, by an adjustable diffraction unit the collimated X-ray beam, while being configured according to a current configuration that is associated with a current wavelength selected out of different wavelengths, the current configuration is selected out of different configurations that are associated with the different wavelengths;
iii. filtering, by the adjustable diffraction unit, the collimated X-ray beam to provide a filtered collimated X-ray beam of the current wavelength; and
iv. focusing, by achromatic focusing optics, the filtered collimated X-ray beam to provide a focused filtered X-ray beam.

16. The method according to claim 15, wherein the adjustable diffraction unit comprises different diffraction elements that are associated with the different wavelengths, and wherein one of the different diffraction elements corresponds to the current configuration.

17. The method according to claim 15, wherein the adjustable diffraction unit comprises a diffraction element and a configuration unit that is configured to determine a Bragg condition of the diffraction element, the Bragg condition corresponds to the current configuration.

18. The method according to claim 15, wherein the adjustable diffraction unit comprises different diffraction elements that are associated with the different wavelengths, and wherein one of the different diffraction elements corresponds to the current configuration.

19. The method according to claim 15, wherein the adjustable diffraction unit comprises a diffraction element and a configuration unit that is configured to determine a Bragg condition of the diffraction element, the Bragg condition corresponds to the current configuration.

20-30. (canceled)
